(19) United States
(12) Patent Application Publication
(10) Pub. No.: US 2013/0241379 A1
(43) Pub. Date: Sep. 19, 2013

(54) COMPUTER CASE COATED WITH ACTIVATED CARBON

(71) Applicant: Lixin ZHANG, GUANGZHONG PROVINCE (CN)

(72) Inventor: Lixin ZHANG, GUANGZHONG PROVINCE (CN)

(73) Assignee: GUANDONG SOHOO TECHNOLOGY CO.,LTD, GUANGZHONG PROVINCE (CN)

(21) Appl. No.: 13/424,355

(22) Filed: Mar. 19, 2012

(51) Int. Cl. H05K 5/02; H05K 7/00

(52) U.S. Cl. 312/237; 312/223.2

(57) ABSTRACT

A computer case coated with activated carbon is provided to absorb the suspended particulates in the air for purifying the air in the case and at the same time purifying the air in the room. The computer case coated with activated carbon includes a case housing. Inside the case housing a coating of activated carbon is applied. The coating of activated carbon purifies the air and guarantees a clean use environment of computer with better performance and longer service life of hardware and is thus suitable for the application in computer cases.

### BACKGROUND OF THE INVENTION

The present invention relates to a computer case. More particularly, the present invention relates to a computer case coated with activated carbon.

In the prior art, a computer case is stored indoors and a fan is mounted inside the case to cool the case down and dispel heat generated while computer components are running into the air. Due to the existence of particulates suspended in the atmosphere, the computer case will be covered with certain amount of dusts around the fan every after a while, consequently impacting the normal circuit actions between each components of the computer and interrupting the use of the computer and shortening its service life due to potential poor contact or short circuit after plugging. The technical defect in the prior art that dust accumulation due to long-term heat dissipation has impact on the normal use of computer has become an urgent technical problem to be solved by the person skilled in the art. In the prior art, the activated carbon and a filter screen are made as a filter to be placed at the inlet of the case, however, with the adoption of such structure, more dust can not be absorbed, an air inlet is easily plugged, and the filter is needed to be frequently cleaned.

### BRIEF SUMMARY OF THE INVENTION

It is a technical object of the present invention to overcome the technological problem of being subjected to dust accumulation in the computer case during the process of normal use, by providing a computer case coated with activated carbon that acts in the use of computer to absorb the suspended particulates in the air for a purpose of purifying the air in the case and at the same time purifying the air in the room.

For realizing the technical object, the invention adopts the following technical scheme:

A computer case coated with activated carbon comprises a case housing, wherein a coating of activated carbon is applied in said case housing.

The coating of activated carbon is applied on the inner side of the case housing.

The coating of activated carbon is applied on the inner side of the case housing in a shape of wave.

The coating of activated carbon is applied on the inner side of the case housing in a shape of screw.

The coating of activated carbon is applied on the surface of each fitting in the case.

The coating of activated carbon is applied on the surface of the hard drive bracket in the case.

The coating of activated carbon is applied on the surface of the video card fixture in the case.

Further, said activated carbon is loaded with F-doped anatase-type TiO₂ in such a way that the activated carbon is dipped in the colloidal sols containing F-doped nanometer TiO₂ for 10 min, and then is taken out and dried.

Further, said activated carbon is fixed on the case housing by a baking varnish method.

Further, a UV-lamp(ultraviolet lamp) is fixed on the inner side of the case housing, and the light of the UV-lamp can irradiate the activated carbon.

In actual applications of the present invention, the coating of activated carbon can serve a excellent role for absorbing the particulate matters that are suspended in the air, e.g. PM2.5 which are any particulate matters with a diameter smaller than or equal to 2.5 microns into the coating of activated carbon, and at the same time absorbing the harmful gas generated while the computer components create heat. It can purify the air in the case and protect the hard drive, the circuit board and the power supply inside the case against the impact of particulate matters that are suspended in the air. It can maintain the computer to operate normally and efficiently and protect the health of computer users. Harmful gases adsorbed by the Activated carbon can be decomposed by the F-doped anatase-type TiO₂ through catalytic reaction, so this feature will last long. The harmful gases generated by the computer case can be purified, and the harmful gases existing in the air can be sucked in by the fan and discharged after purification. Therefore, the case has the function of an air purifier to protect the health of users.

The present invention has the following beneficial technical effects: the coating of activated carbon utilized purifies the air and guarantees the clean use environment of computer with better hardware performance and longer service life; the coating of activated carbon in a shape of wave utilized increases the contact surface between the air and the coating of activated carbon and further improves absorption of particulate matters that are suspended in the air; the coating of activated carbon in a shape of screw utilized increases the contact surface with the air, has a function of air connectivity and completely purifies the air in the case. The UV-lamp together with the activated carbon loaded with F-doped anatase-type TiO₂ can not only kill bacteria in the air, but also make the toxic gases such as Formaldehyde nontoxic. It is a case housing which has the function of an air purifier. The present invention in application, can reduce and eliminate electromagnetic radiation towards external environment by the computer, and avoid the influence on human health.

### BRIEF DESCRIPTION OF THE DRAWINGS

FIG. 1 is a structural diagram of the first model of the case in an embodiment of the present invention.

FIG. 2 is a structural diagram of the second model of the case in an embodiment of the present invention.

### DETAILED DESCRIPTION OF THE INVENTION

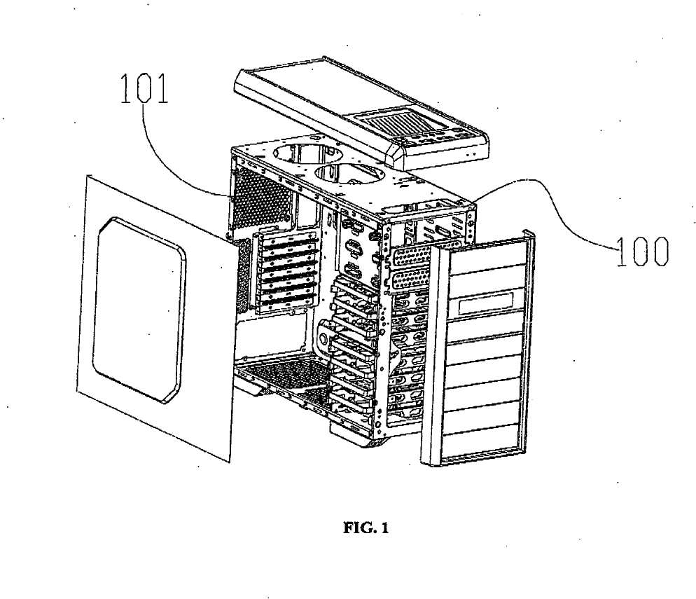

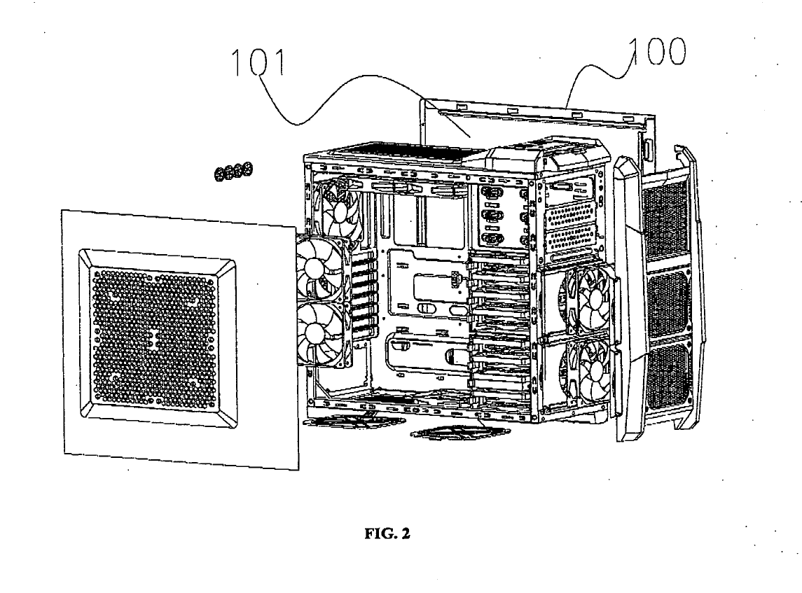

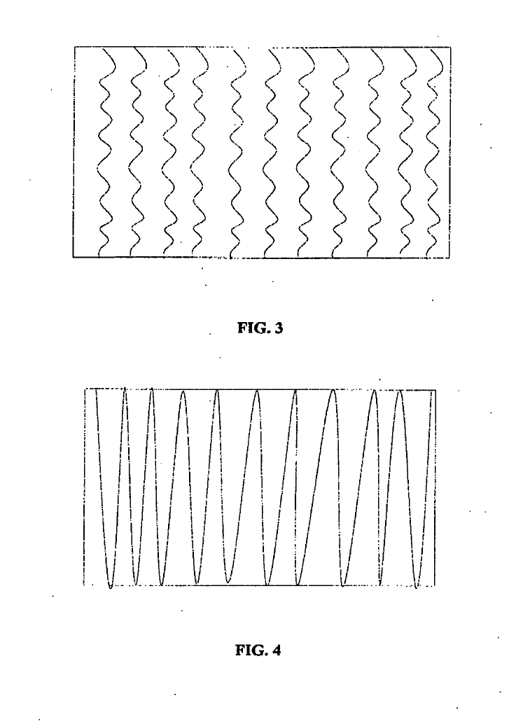

FIGS. 1 and 2 jointly describe in details the embodiments of the present invention but make no limits to any of the claims.

The computer case coated with activated carbon comprises a case housing 100. Inside said case housing 100 a coating of activated carbon 101 is applied. The coating of activated carbon 101 is applied on the inner side of the case housing 100 in a shape of wave. In an embodiment, the coating of activated carbon 101 is applied on the inner side of the case housing 100 in a shape of screw. In another embodiment of the present invention, a coating of activated carbon is applied on the surface of the hard drive bracket in the case housing 100, and the coatings of activated carbon are applied on the surface of each fitting, the surface of each wire clip and the surface of the video card fixture in the case housing 100. In actual applications of the present invention, the coating of activated carbon serves an excellent role for absorbing the particulate matters that are suspended in the air, e.g. PM2.5 which are any particulate matters with a diameter smaller than or equal to 2.5 microns, and at the same time absorbing the harmful gases that are generated while the while computer components create heat. It can purify the air in the case and protect the hard drive, the circuit board and the power supply inside the case against the impact of particulate matters that are suspended in the air. It can maintain the computer to operate normally and efficiently.

The present invention purifies the air and guarantees the clean use environment of computer with better hardware performance and longer service life and that is suitable for the application in computer cases. It is an invention as well as a innovation in the art with outstanding practical features and excellent technological effects.

1. (canceled)

2. A computer case coated with activated carbon, comprising a case housing, wherein a coating of activated carbon is applied on an inner side of the case housing.

3. The computer case coated with activated carbon of claim 2, wherein said coating of activated carbon is applied on the inner side of the case housing in a shape of wave.

4. The computer case coated with activated carbon of claim 2, wherein said coating of activated carbon is applied on the inner side of the case housing in a shape of screw.

5-11. (canceled)
